(19) United States
(12) Patent Application Publication
(10) Pub. No.: US 2015/0271465 A1
(43) Pub. Date: Sep. 24, 2015

(54) AUDIO/VIDEO SYSTEM WITH USER ANALYSIS AND METHODS FOR USE THEREWITH

(71) Applicant: ViXS Systems, Inc., Toronto (CA)

(72) Inventor: Sally Jean Daub, Toronto (CA)

(73) Assignee: ViXS Systems, Inc., Toronto (CA)

(21) Appl. No.: 14/217,867

(22) Filed: Mar. 18, 2014

(51) Int. Cl. H04N 13/00; H03G 7/00; H04N 5/57

(52) U.S. Cl. CPC H04N 13/0051; H04N 5/57; H03G 7/007

(57) ABSTRACT

A system for use with an audio/video (A/V) display device includes a viewer sensor that generates sensor data in a presentation area of the A/V player. A user analysis module analyzes the sensor data to detect a number of users of the A/V player. The user analysis module generates, based on the analysis of the sensor data, A/V control data for controlling at least one of: an audio control parameter and a video control parameter of the A/V player.

### CROSS REFERENCE TO RELATED PATENTS

None

### TECHNICAL FIELD

The present disclosure relates to audio/video systems that process and present audio and/or display video signals.

### DESCRIPTION OF RELATED ART

Modern users have many options to view audio/video programming. Home media systems can include a television, home theater audio system, a set top box and digital audio and/or video player. The user typically is provided one or more remote control devices that respond to direct user interactions such as buttons, keys or a touch screen to control the functions and features of the device.

Audio/video content is also available via a personal computer, smartphone or other device. Such devices are typically controlled via a buttons, keys, a mouse or other pointing device or a touch screen.

### BRIEF DESCRIPTION OF THE SEVERAL VIEWS OF THE DRAWINGS

FIGS. 1-4 present pictorial diagram representations of various video devices in accordance with embodiments of the present disclosure.

FIG. 5 presents a block diagram representation of a system in accordance with an embodiment of the present disclosure.

FIG. 6 presents a block diagram representation of a user analysis module in accordance with an embodiment of the present disclosure.

FIG. 7 presents a pictorial representation of a presentation area in accordance with an embodiment of the present disclosure.

FIG. 8 presents a flowchart representation of a method in accordance with an embodiment of the present disclosure.

### DETAILED DESCRIPTION

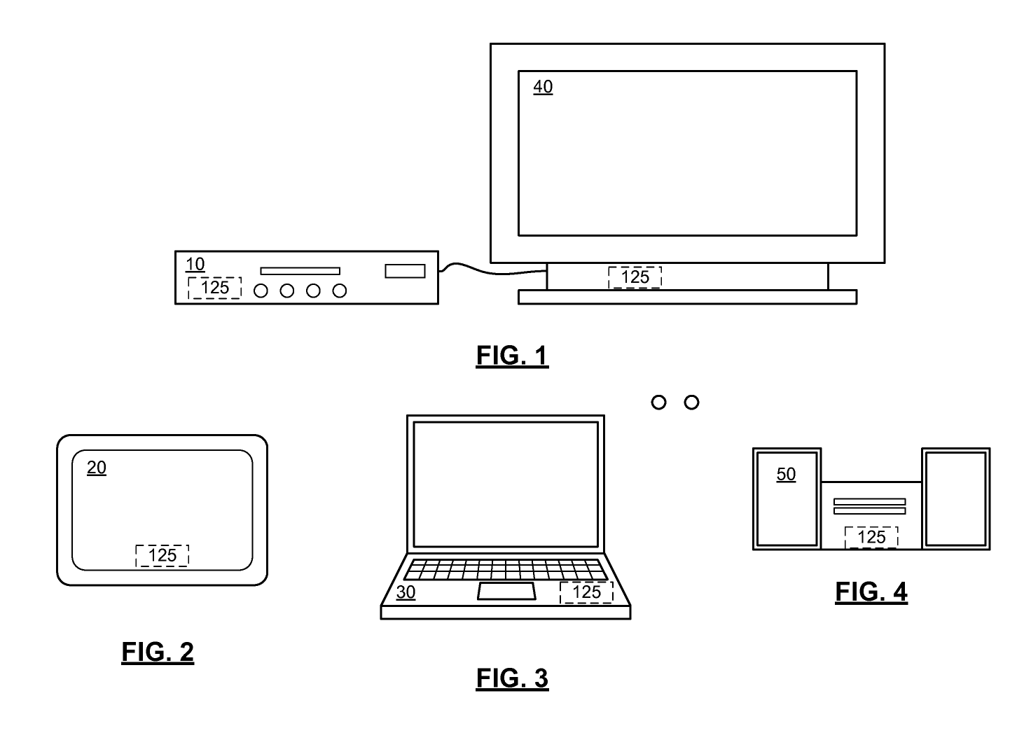

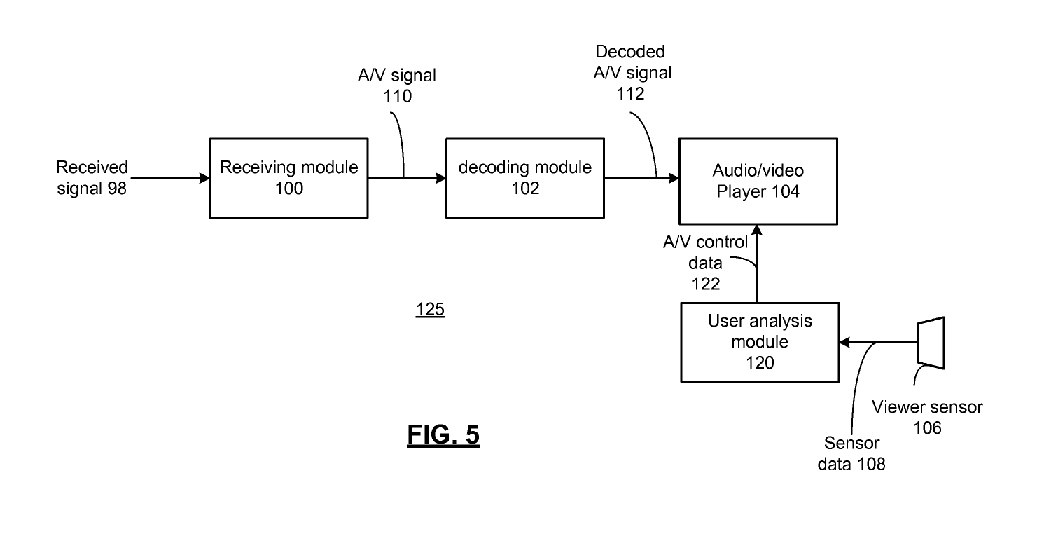

FIGS. 1-4 present pictorial diagram representations of various video devices in accordance with embodiments of the present disclosure. In particular, device 10 represents a set top box with or without built-in digital video recorder functionality or a stand-alone digital video player such as an internet video player, Blu-ray player, digital video disc (DVD) player or other video player. Device 20 represents a tablet computer, smartphone or other communications device. Device 30 represents a laptop, netbook or other portable computer. Device 40 represents a video display device such as a television or monitor. Device 50 represents an audio player such as a compact disc (CD) player, a MP3 player or other audio player.

The devices 10, 20, 30, 40 and 50 each represent examples of electronic devices that incorporate one or more elements of a system 125 that includes features or functions of the present disclosure. While these particular devices are illustrated, system 125 includes any device or combination of devices that is capable of performing one or more of the functions and features described in conjunction with FIGS. 5-8 and the appended claims.

FIG. 5 presents a block diagram representation of a system in accordance with an embodiment of the present disclosure. In an embodiment, this system includes a receiving module 100, such as a television receiver, cable television receiver, satellite broadcast receiver, broadband modem, 3G or 4G transceiver or other information receiver or transceiver that is capable of receiving a received signal 98 and extracting one or more audio/video signals 110.

The received signal 98 can be a broadcast video signal, such as a television signal, high definition television signal, enhanced definition television signal or other broadcast video signal that has been transmitted over a wireless medium, either directly or through one or more satellites or other relay stations or through a cable network, optical network or other transmission network. In addition, received signal 98 can be generated from a stored video file, played back from a recording medium such as a magnetic tape, magnetic disk or optical disk, and can include a streaming video signal that is transmitted over a public or private network such as a local area network, wide area network, metropolitan area network or the Internet.

Received signal 98 can include a compressed digital video signal complying with a digital video codec standard such as H.264, MPEG-4 Part 10 Advanced Video Coding (AVC), VC-1, H.265, or another digital format such as a Motion Picture Experts Group (MPEG) format (such as MPEG1, MPEG2 or MPEG4), QuickTime format, Real Media format, Windows Media Video (WMV) or Audio Video Interleave (AVI), etc. When the received signal 98 includes a compressed digital video signal, a decoding module 102 or other video codec decompresses the audio/video signal 110 to produce a processed audio/video signal 112 suitable for display by a video display device of audio/video player 104 that creates an optical image stream either directly or indirectly, such as by projection.

In addition or in the alternative embodiment, the received signal 98 can include an audio component of a video signal, a broadcast audio signal, such as a radio signal, high definition radio signal or other audio signal that has been transmitted over a wireless medium, either directly or through one or more satellites or other relay stations or through a cable network, optical network or other transmission network. In addition, received signal 98 can be an audio component of a stored video file or streamed video signal, an MPEG3 (MP3) or other digital audio signal generated from a stored audio file, played back from a recording medium such as a magnetic tape, magnetic disk or optical disk, and can include a streaming audio signal that is transmitted over a public or private network such as a local area network, wide area network, metropolitan area network or the Internet.

When the received signal 98 includes a compressed digital audio signal, the decoding module 102 can decompress the audio/video signal 110 and otherwise process the audio/video signal 110 to produce a processed audio signal suitable for presentation by an audio player included in audio/video player 104.

The audio/video signal 112 can include a high definition media interface (HDMI) signal, digital video interface (DVI) signal, a composite video signal, a component video signal, a S-video signal, and/or one or more analog or digital audio signals.

In an embodiment, the received signal 98 is scrambled or encrypted and the receiving module operates to descramble and/or decrypt the received signal 98 to produce the audio/video signal 110.

In operation, a viewer sensor 106 generates sensor data 108 in a presentation area of the A/V player 104. The viewer sensor 106 can include a digital camera such as a still or video camera that is either a stand-alone device, or is incorporated in any one of the devices 10, 20, 30 or 40 or other device that generates sensor data 108 in the form of image data. In addition or in the alternative, the viewer sensor 106 can include an infrared sensor, thermal imager, background temperature sensor or other thermal sensor, an ultrasonic sensor or other sonar-based sensor, a proximity sensor, an audio sensor such as a microphone, a motion sensor, brightness sensor, wind speed sensor, humidity sensor and/or other sensor for generating sensor data 108 that can be used by viewer analysis module 120 for determining the presence of viewers, for identifying particular viewers and/or for characterizing their activities.

A user analysis module 120 analyzes the sensor data 108 to generate the A/V control data 122. For example, the user analysis module 120 analyzes the sensor data 108 to detect a number of users of the A/V player 104 and their activities. The user analysis module 120 generates, based on the analysis of the sensor data 108, A/V control data 122 for controlling the A/V player 104. The AV control data 122 can include one or more audio control parameters, such as volume, dynamic range, and individual speaker controls or other audio parameters and/or one or more video control parameters such as pause, resume, contrast, brightness, three-dimensional (3D) presentation angle or other video parameters.

In an embodiment, user analysis module 120 generates an audio control parameter to reduce an audio volume when the number of users is zero. The user analysis module 120 can analyze the sensor data 108 to detect at least one viewing angle corresponding to the number of users and generates a video control parameter to control a three-dimensional presentation angle in response to the at least one viewing angle. The user analysis module 120 can analyze the sensor data 108 to determine an activity corresponding to at least one of the number of users and generates the A/V control data 122 based on the activity.

In an embodiment, the user analysis module 120 generates an audio parameter to reduce the audio volume when one or more of the users are sleep. The user analysis module 120 can generate and an audio parameter to reduce the audio volume to a subset of speakers when a first non-null proper subset of the number of users are determined to be asleep and a second non-null proper subset of the number of users are determined to be awake. The user analysis module 120 can generate an audio parameter to reduce the audio volume when one or more users are engaged in conversation. Further, the user analysis module can generate the video parameter to reduce one of: a brightness and a contrast, when the analysis of user activities indicates a lack of attention by one or more users to the A/V player 104.

Consider an example where a family is watching TV. One or more video cameras are stand-alone devices or are built into the TV, a set top, Blu-Ray player, or mobile devices associated with the users. The camera or cameras capture video of the presentation environment and users. The system 125 processes the video and detects from it if there are users' present, how many users are present, and further the activities engaged in by each of the users. In particular, the system 125 determines which users are watching closely, from what angles they are watching, which users are not watching closely or engaged in a conversation, which users are not watching at all, and which users are asleep, etc.

The system 125, based on the information above, can automatically adjust its playback settings of the A/V player 104 accordingly. In particular, the volume can be turned down if viewers are talking or sleeping or not present. The video can be paused and/or video brightness/contrast or audio dynamic range can be adjusted if viewers are not watching or not listening. A video can be resumed and/or the audio and video parameters can be returned to normal when viewers return, awake, return their attention to the programming, etc. The 3D playback may be adjusted based on the viewers' watching angles, etc.

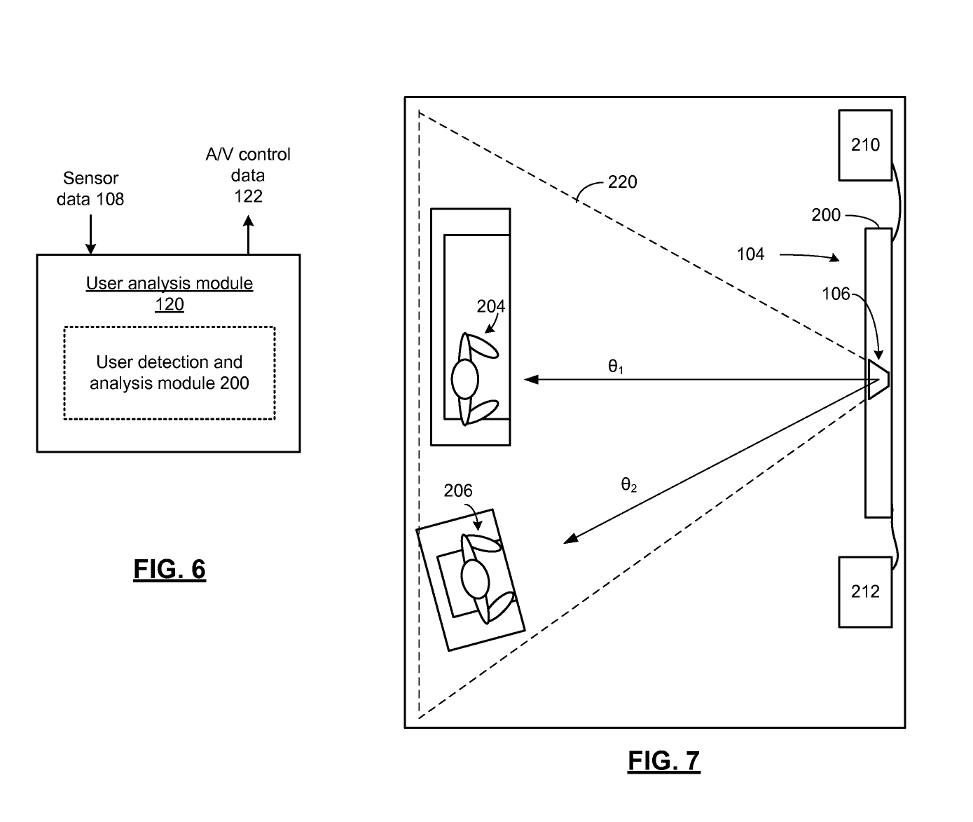

Further embodiments including several optional functions and features are presented in conjunction with FIGS. 6-8 that follow.

FIG. 6 presents a block diagram representation of a user analysis module in accordance with an embodiment of the present disclosure. In particular, a user analysis module 120 is presented that includes a user detection and analysis module 200.

A user analysis module 120 analyzes the sensor data 108 to generate A/V control data 122. In an embodiment, the user detection and analysis module 200 analyzes the sensor data 108 to determine a number of users that are present, the locations of the users, the viewing angle for each of the users and further user activities that indicate, for example, the user's level of interest in the audio or video content being presented or otherwise displayed. These factors can be used to determine the A/V control data 122 via a look-up table, state machine, algorithm or other logic.

In one mode of operation, the user detection and analysis module 200 analyzes sensor data 108 in the form of image data together with a skin color model used to roughly partition face candidates. The user detection and analysis module 200 identifies and tracks candidate facial regions over a plurality of images (such as a sequence of images of the image data) and detects a face in the image based on the one or more of these images. For example, user detection and analysis module 200 can operate via detection of colors in the image data. The user detection and analysis module 200 generates a color bias corrected image from the image data and a color transformed image from the color bias corrected image. The user detection and analysis module 200 then operates to detect colors in the color transformed image that correspond to skin tones. In particular, user detection and analysis module 200 can operate using an elliptic skin model in the transformed space such as a C_{b}Cᵣ subspace of a transformed YC_{b}Cᵣ space. In particular, a parametric ellipse corresponding to contours of constant Mahalanobis distance can be constructed under the assumption of Gaussian skin tone distribution to identify a facial region based on a two-dimension projection in the C_{b}Cᵣsubspace. As exemplars, the 853,571 pixels corresponding to skin patches from the Heinrich-Hertz-Institute image database can be used for this purpose, however, other exemplars can likewise be used in broader scope of the present disclosure.

In an embodiment, the user detection and analysis module 200 tracks candidate facial regions over a sequence of images and detects a facial region based on an identification of facial motion in the candidate facial region over the sequence of images. The facial motion can includes eye movement, mouth movement and/or other head or body movements. For example, face candidates can be validated for face detection based on the further recognition by user detection and analysis module 200 of facial features, like eye blinking (both eyes blink together, which discriminates face motion from others; the eyes are symmetrically positioned with a fixed separation, which provides a means to normalize the size and orientation of the head.), shape, size, motion and relative position of face, eyebrows, eyes, nose, mouth, cheekbones and jaw. Any of these facial features can be used extracted from the image data and used by user detection and analysis module 200 to eliminate false detections.

Further, the user detection and analysis module 200 can employ temporal recognition to extract three-dimensional features based on different facial perspectives included in the plurality of images to improve the accuracy of the recognition of the face. Using temporal information, the problems of face detection including poor lighting, partially covering, size and posture sensitivity can be partly solved based on such facial tracking. Furthermore, based on profile view from a range of viewing angles, more accurate and 3D features such as contour of eye sockets, nose and chin can be extracted.

Based on the number facial regions that are detected, the number of users present can be identified. In addition, the user detection and analysis module 200 can identify the viewing angle of the users that are present based on the position of the detected faces in the field of view of the image data. In addition, the activities being performed by each user can be determined based on an extraction of facial characteristic data such as relative position of face, position and condition of the eyebrows, eyes, nose, mouth, cheekbones and jaw, etc.

In addition to detecting an identifying the particular users, the user detection and analysis module 200 can further analyze the faces of the users to determine a level of interest in particular content. In an embodiment, the image capture device is incorporated in the video display device such as a TV or monitor or is otherwise positioned so that the position and orientation of the users with respect to the video display device can be detected. In an embodiment the orientation of the face is determined to indicate whether or not the user is facing the video display device. In this fashion, when the user's head is down or facing elsewhere, the user's level of interest in the content being displayed is low. Likewise, if the eyes of the user are closed for an extended period indicating sleep, the user's interest in the displayed content can be determined to be low. If, on the other hand, the user is facing the video display device and/or the position of the eyes and condition of the mouth indicate a heighten level of awareness, the user's interest can be determined to be high.

For example, a user can be determined to be watching closely if the face is pointed at the display screen and the eyes are open except during blinking events. Further other aspects of the face such as the eyebrows and mouth may change positions indicating that the user is following the display with interest. A user can be determined to be not watching closely if the face is not pointed at the display screen for more than a transitory period of time. A user can be determined to be engaged in conversation if the face is not pointed at the display screen for more than a transitory period of time, audio conversation is detected from one or more viewers, the face is pointed toward another user and/or if the mouth of the user is moving. A user can be determined to be sleeping if the eyes of the user are closed for more than a transitory period of time and/or if other aspects of the face such as the eyebrows and mouth fail to change positions over an extended period of time.

FIG. 7 presents a pictorial representation of a presentation area in accordance with an embodiment of the present disclosure. In particular, the use of an example system 125 presented in conjunction with FIG. 4 is shown. In this example, a viewer sensor 106 generates sensor data 108 in a presentation area 220 of the A/V player 104. The A/V player 104 includes a flat screen television 200 and speakers 210 and 212. The viewer sensor can include a digital camera such as a still or video camera that is either a stand-alone device, or is incorporated the flat screen television 200 and that generates sensor data 108 that includes image data.

The user analysis module 120 analyzes the sensor data 108 to detect the users 204 and 206 of the A/V player 104 and their activities. The user analysis module 120 generates, based on the analysis of the sensor data 108, A/V control data 122 for controlling the A/V player 104. The AV control data 122 can include one or more audio control parameters, such as volume, dynamic range, and individual speaker controls or other audio parameters and/or one or more video control parameters such as contrast, brightness, three-dimensional (3D) presentation angle or other video parameters.

Consider the case where 3D programming is being presented, the user analysis module 120 can analyze the sensor data 108 to detect the viewing angles θ₁ and θ₂ corresponding to the users 204 and 206 respectively and generate a video control parameter to control the three-dimensional presentation angle in response. If one of the users 204 or 206 were to leave the room, the 3D presentation angle could be adjusted to match the angle of the remaining user for optimum viewing. Further, when one of the users 204 or 206 is asleep and the other is awake, the 3D presentation angle can be adjusted to correspond to the viewer that is awake for optimum viewing. Further, when one of the users 204 is asleep and the other user is awake, the user analysis module 120 generates an audio parameter to reduce the audio volume to the speaker or speakers nearest the user that is asleep. For example, if user 206 is asleep and user 204 is awake, the volume of speaker 212 could be reduced.

In another example, if the sensor data 108 indicates that the users 204 and 206 are engaged in a conversation with one another, audio control parameters can be generated to reduce the volume for both speakers 210 and 212.

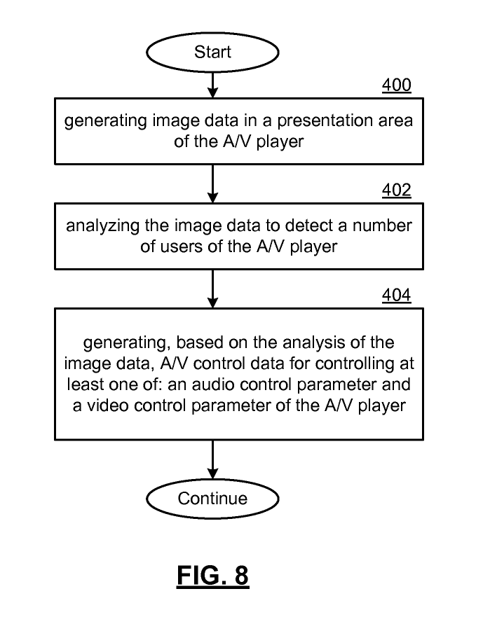

FIG. 8 presents a flowchart representation of a method in accordance with an embodiment of the present disclosure. In particular, a method is presented for use in with one or more features described in conjunction with FIGS. 1-7. Step 400 includes generating image data in a presentation area of the A/V player. Step 402 includes analyzing the image data to detect a number of users of the A/V player. Step 404 includes generating, based on the analysis of the image data, A/V control data for controlling at least one of: an audio control parameter and a video control parameter of the A/V player.

In an embodiment, the audio control parameter is generated to reduce an audio volume when the number of users is zero. The image data can be analyzed to detect at least one viewing angle corresponding to the number of users and the video control parameter can be generated to control a three-dimensional presentation angle in response to the at least one viewing angle.

In an embodiment, the image data is analyzed to determine an activity corresponding to at least one of the number of users and the A/V control data can be generated based on the activity. An audio parameter can be generated to reduce the audio volume when the activity is sleep. An audio parameter can be generated to reduce the audio volume a subset of speakers when a first non-null proper subset of the number of users are determined to be asleep and a second non-null proper subset of the number of users are determined to be awake. An audio parameter can be generated to reduce the audio volume when the activity is conversation. A video parameter is generated to reduce one of: a brightness, and a contrast, when the activity indicates a lack of attention to the A/V player.

As may also be used herein, the term(s) “configured to”, “operably coupled to”, “coupled to”, and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”. As may even further be used herein, the term “configured to”, “operable to”, “coupled to”, or “operably coupled to” indicates that an item includes one or more of power connections, input(s), output(s), etc., to perform, when activated, one or more its corresponding functions and may further include inferred coupling to one or more other items. As may still further be used herein, the term “associated with”, includes direct and/or indirect coupling of separate items and/or one item being embedded within another item.

As may also be used herein, the terms “processing module”, “processing circuit”, “processor”, and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, and/or processing unit may be, or further include, memory and/or an integrated memory element, which may be a single memory device, a plurality of memory devices, and/or embedded circuitry of another processing module, module, processing circuit, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, and/or processing unit executes, hard coded and/or operational instructions corresponding to at least some of the steps and/or functions illustrated in one or more of the Figures. Such a memory device or memory element can be included in an article of manufacture.

One or more embodiments have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

In addition, a flow diagram may include a “start” and/or “continue” indication. The “start” and “continue” indications reflect that the steps presented can optionally be incorporated in or otherwise used in conjunction with other routines. In this context, “start” indicates the beginning of the first step presented and may be preceded by other activities not specifically shown. Further, the “continue” indication reflects that the steps presented may be performed multiple times and/or may be succeeded by other by other activities not specifically shown. Further, while a flow diagram indicates a particular ordering of steps, other orderings are likewise possible provided that the principles of causality are maintained.

The one or more embodiments are used herein to illustrate one or more aspects, one or more features, one or more concepts, and/or one or more examples. A physical embodiment of an apparatus, an article of manufacture, a machine, and/or of a process may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

The term “module” is used in the description of one or more of the embodiments. A module implements one or more functions via a device such as a processor or other processing device or other hardware that may include or operate in association with a memory that stores operational instructions. A module may operate independently and/or in conjunction with software and/or firmware. As also used herein, a module may contain one or more sub-modules, each of which may be one or more modules.

While particular combinations of various functions and features of the one or more embodiments have been expressly described herein, other combinations of these features and functions are likewise possible. The present disclosure is not limited by the particular examples disclosed herein and expressly incorporates these other combinations.

What is claimed is:

1. A system for use with an audio/video (A/V) player, the system comprising:
a viewer sensor that generates sensor data in a presentation area of the A/V player; and
a user analysis module, coupled to the image capture device, that analyzes the sensor data to detect a number of users of the A/V player and that generates, based on the analysis of the sensor data, A/V control data for controlling at least one of: an audio control parameter and a video control parameter of the A/V player.

2. The system of claim 1 wherein the user analysis module generates the audio control parameter to reduce an audio volume when the number of users is zero.

3. The system of claim 1 wherein the user analysis module analyzes the sensor data to detect at least one viewing angle corresponding to the number of users and the video control parameter can be generated to control a three-dimensional presentation angle in response to the at least one viewing angle.

4. The system of claim 1 wherein the user analysis module analyzes the sensor data to determine an activity corresponding to at least one of the number of users and generates the A/V control data based on the activity.

5. The system of claim 4 wherein the user analysis module generates the audio parameter to reduce the audio volume when the activity is sleep.

6. The system of claim 5 wherein the user analysis module generates the audio parameter to reduce the audio volume to a subset of speakers when a first non-null proper subset of the number of users are determined to be asleep and a second non-null proper subset of the number of users are determined to be awake.

7. The system of claim 4 wherein the user analysis module generates the audio parameter to reduce the audio volume when the activity is conversation.

8. The system of claim 4 wherein the user analysis module generates the video parameter to reduce one of: a brightness and a contrast, when the activity indicates a lack of attention to the A/V player.

9. The system of claim 1 wherein the viewer sensor includes an image capture device and the sensor data includes image data.

10. A method with an audio/video (A/V) player, the method comprising:
generating image data in a presentation area of the A/V player;
analyzing the image data to detect a number of users of the A/V player; and
generating, based on the analysis of the image data, A/V control data for controlling at least one of: an audio control parameter and a video control parameter of the A/V player.

11. The method of claim 10 wherein the audio control parameter is generated to reduce an audio volume when the number of users is zero.

12. The method of claim 10 wherein the image data is analyzed to detect at least one viewing angle corresponding to the number of users and generates the video control parameter to control a three-dimensional presentation angle in response to the at least one viewing angle.

13. The method of claim 10 wherein the image data is analyzed to determine an activity corresponding to at least one of the number of users and the A/V control data is generated based on the activity.

14. The method of claim 13 wherein the audio parameter is generated to reduce the audio volume when the activity is sleep.

15. The method of claim 14 the audio parameter is generated to reduce the audio volume a subset of speakers when a first non-null proper subset of the number of users are determined to be asleep and a second non-null proper subset of the number of users are determined to be awake.

16. The method of claim 13 wherein the audio parameter is generated to reduce the audio volume when the activity is conversation.

17. The method of claim 13 wherein the video parameter is generated to reduce one of: a brightness and a contrast, when the activity indicates a lack of attention to the A/V player.
